(19) United States
(12) Patent Application Publication
(10) Pub. No.: US 2026/0171746 A1
(43) Pub. Date: Jun. 18, 2026

(54) LASER APPARATUS AND ELECTRONIC DEVICE MANUFACTURING METHOD

(71) Applicants: Gigaphoton Inc., Tochigi (JP); Inter-University Research Institute Corporation, National Institutes of Natural Sciences, Tokyo (JP)

(72) Inventors: Yuki TAMARU, Oyama-shi (JP); Taisuke MIURA, Oyama-shi (JP); Ryo YASUHARA, Toki-shi (JP)

(73) Assignees: Gigaphoton Inc., Tochigi (JP); Inter-University Research Institute Corporation, National Institutes of Natural Sciences, Tokyo (JP)

(21) Appl. No.: 19/532,569

(22) Filed: Feb. 6, 2026

Related U.S. Application Data
(63) Continuation of application No. PCT/JP2023/033333, filed on Sep. 13, 2023.

(51) Int. Cl. H01S 3/10; G03F 7/00; G03F 7/20; H01S 3/08; H01S 3/23

(52) U.S. Cl. CPC H01S 3/10061; G03F 7/2004; G03F 7/70025; H01S 3/08054; H01S 3/10007; H01S 3/2308

(57) ABSTRACT

A laser apparatus according to an aspect of the present disclosure includes: an optical isolator disposed in an optical path between an oscillation-stage laser and an amplification-stage laser configured to amplify, as seed light, linearly polarized pulse laser light output from the oscillation-stage laser and having an ultraviolet wavelength, the optical isolator including a first Faraday rotator configured to rotate a polarization direction of the pulse laser light output from the oscillation-stage laser by a first angle in a first rotation direction by a magnetic field in a first direction, a first polarizer having normalized transmittance greater than or equal to 0.9 for the pulse laser light output from the first Faraday rotator, and a second Faraday rotator configured to rotate the polarization direction of the pulse laser light passing through the first polarizer by a second angle in a second rotation direction opposite to the first rotation direction by a magnetic field in a second direction opposite to the first direction; and a second polarizer disposed in an optical resonator of the amplification-stage laser and having normalized transmittance greater than or equal to 0.9 for the seed light.

### CROSS-REFERENCE TO RELATED APPLICATIONS

The present application is a continuation application of International Application No. PCT/JP2023/033333, filed on Sep. 13, 2023, the entire contents of which are hereby incorporated by reference.

### BACKGROUND

### 1. Technical Field

The present disclosure relates to a laser apparatus and an electronic device manufacturing method.

### 2. Related Art

In recent years, a semiconductor exposure apparatus is required to improve the resolution thereof as semiconductor integrated circuits are increasingly miniaturized and highly integrated. To this end, reduction in the wavelength of light emitted from a light source for exposure is underway. For example, a KrF excimer laser apparatus, which outputs laser light having a wavelength of about 248 nm, and an ArF excimer laser apparatus, which outputs laser light having a wavelength of about 193 nm, are used as a gas laser apparatus for exposure.

The light from KrF and ArF excimer laser apparatuses performing spontaneous laser oscillation has a wide spectral linewidth ranging from 350 to 400 μm. A projection lens made of a material that transmits ultraviolet light, such as the KrF and ArF laser light, therefore produces chromatic aberrations in some cases. As a result, the resolution of the projection lens may decrease. To avoid the decrease in the resolution, the spectral linewidth of the laser light output from the gas laser apparatus needs to be narrow enough to make the chromatic aberrations negligible. To this end, a line narrowing module (LNM) including a line narrowing element (such as etalon or grating) is provided in some cases in a laser resonator of the gas laser apparatus to narrow the spectral linewidth. A gas laser apparatus providing a narrowed spectral linewidth is hereinafter referred to as a narrowed-line gas laser apparatus.

### CITATION LIST

### Patent Literature

PTL 1: WO2022/195893A
PTL 2: JP-A-2006-165484

### SUMMARY

A laser apparatus according to an aspect of the present disclosure includes: an oscillation-stage laser; an amplification-stage laser configured to amplify, as seed light, linearly polarized pulse laser light output from the oscillation-stage laser and having an ultraviolet wavelength; an optical isolator disposed in an optical path between the oscillation-stage laser and the amplification-stage laser, the optical isolator including a first Faraday rotator configured to rotate a polarization direction of the pulse laser light output from the oscillation-stage laser by a first angle in a first rotation direction by a magnetic field in a first direction, a first polarizer having normalized transmittance greater than or equal to 0.9 for the pulse laser light output from the first Faraday rotator, and a second Faraday rotator configured to rotate the polarization direction of the pulse laser light passing through the first polarizer by a second angle in a second rotation direction opposite to the first rotation direction by a magnetic field in a second direction opposite to the first direction; and a second polarizer disposed in an optical resonator of the amplification-stage laser and having normalized transmittance greater than or equal to 0.9 for the seed light.

A laser apparatus according to another aspect of the present disclosure includes: an oscillation-stage laser; an amplification-stage laser configured to amplify, as seed light, linearly polarized pulse laser light output from the oscillation-stage laser and having an ultraviolet wavelength; an optical isolator disposed in an optical path between the oscillation-stage laser and the amplification-stage laser, the optical isolator including a first Faraday rotator configured to rotate a polarization direction of the pulse laser light output from the oscillation-stage laser by a first angle in a first rotation direction by a magnetic field in a first direction, a first polarizer having normalized transmittance greater than or equal to 0.9 for the pulse laser light output from the first Faraday rotator, and a second Faraday rotator configured to rotate the polarization direction of the pulse laser light passing through the first polarizer by a second angle in a direction that is the same as the first rotation direction by a magnetic field in a direction that is the same as the first direction; and a second polarizer disposed in an optical resonator of the amplification-stage laser and having normalized transmittance greater than or equal to 0.9 for the seed light.

An electronic device manufacturing method according to another aspect of the present disclosure includes: generating laser light amplified by an amplification-stage laser of a laser apparatus; outputting the amplified laser light to an exposure apparatus; and exposing a photosensitive substrate to the laser light in the exposure apparatus to manufacture electronic devices, the laser apparatus including an oscillation-stage laser, an amplification-stage laser configured to amplify, as seed light, linearly polarized pulse laser light output from the oscillation-stage laser and having an ultraviolet wavelength, an optical isolator disposed in an optical path between the oscillation-stage laser and the amplification-stage laser, the optical isolator including a first Faraday rotator configured to rotate a polarization direction of the pulse laser light output from the oscillation-stage laser by a first angle in a first rotation direction by a magnetic field in a first direction, a first polarizer having normalized transmittance greater than or equal to 0.9 for the pulse laser light output from the first Faraday rotator, and a second Faraday rotator configured to rotate the polarization direction of the pulse laser light passing through the first polarizer by a second angle in a second rotation direction opposite to the first rotation direction by a magnetic field in a second direction opposite to the first direction, and a second polarizer disposed in an optical resonator of the amplification-stage laser and having normalized transmittance greater than or equal to 0.9 for the seed light.

### BRIEF DESCRIPTION OF DRAWINGS

Some embodiments of the present disclosure will be described below only by way of example with reference to the accompanying drawings.

FIG. 1 is an explanatory diagram for polarized light.

FIG. 2 shows graphs illustrating the relationship between the angle of incidence of light incident from the air on calcium fluoride and the reflectance for an S-polarization component and a P-polarization component.

FIG. 3 is an explanatory diagram schematically showing a case where a window of a chamber of an excimer laser is disposed at Brewster's angle in an optical resonator.

FIG. 4 schematically shows the configuration of a laser apparatus according to Comparative Example.

FIG. 5 shows problems with the laser apparatus according to Comparative Example.

FIG. 6 schematically shows the configuration of an optical isolator according to Comparative Example, which suppresses return light.

FIG. 7 schematically shows the configuration of a laser apparatus according to a first embodiment.

FIG. 8 is a cross-sectional view schematically showing the configuration of a Faraday rotator.

FIG. 9 is a table showing preferable ranges of a magnetic field and the thickness of a Faraday material in a case where the wavelength of pulse laser light is the wavelength at which an ArF excimer laser performs oscillation.

FIG. 10 is a table showing preferable ranges of the magnetic field and the thickness of the Faraday material in a case where the wavelength of the pulse laser light is the wavelength at which a KrF excimer laser performs oscillation.

FIG. 11 shows a graph illustrating the relationship of the angular difference between the transmission axis of a polarizer and the polarization direction of the pulse laser light with an extinction ratio, and a graph of the extinction ratio converted into normalized transmittance.

FIG. 12 schematically shows the configuration of a laser apparatus according to a second embodiment.

FIG. 13 schematically shows the configuration of an amplification-stage laser of the laser apparatus according to the second embodiment.

FIG. 14 shows graphs showing the relationship between transmittance Tp for the P-polarized light and the angle of incidence with respect to windows disposed in an in optical resonator of the amplification-stage laser shown in FIG. 13, and the relationship between a ratio (Ts/Tp) of transmittance Ts for the S-polarized light to the transmittance Tp for the P-polarized light and the angle of incidence of the light incident on the windows.

FIG. 15 is an explanatory diagram showing the optical path of the S-polarization component of the pulse laser light propagating in a window disposed at Brewster's angle.

FIG. 16 schematically shows the configuration of a laser apparatus according to a third embodiment.

FIG. 17 schematically shows the configuration of a laser apparatus according to a fourth embodiment.

FIG. 18 schematically shows the configuration of an amplification-stage laser of the laser apparatus according to the fourth embodiment.

FIG. 19 is an explanatory diagram showing the optical path of the S-polarization component of the pulse laser light propagating through a plane parallel substrate and a window that are disposed at Brewster's angle.

FIG. 20 schematically shows the configuration of an exposure apparatus.

### DETAILED DESCRIPTION

### Contents

1. Description of terms
1.1 Polarizer
1.2 Polarized light
1.3 Brewster's angle
1.4 Normalized transmittance
2. Overview of laser apparatus according to Comparative Example
2.1 Configuration
2.2 Operation
3. Problems
4. First embodiment

4.1 Configuration
4.2 Operation
4.3 Specific example of Faraday rotators
4.4 Allowable angular difference between transmission axis of polarizer and polarization direction of laser light
4.5 Effects and advantages
5. Second embodiment
5.1 Configuration
5.2 Operation
5.3 Effects and advantages
6. Third embodiment
6.1 Configuration
6.2 Operation
6.3 Effects and advantages
7. Fourth embodiment
7.1 Configuration
7.2 Operation
7.3 Effects and advantages
8. Electronic device manufacturing method
9. Others

Embodiments of the present disclosure will be described below in detail with reference to the drawings. The embodiments described below show some examples of the present disclosure and are not intended to limit the contents of the present disclosure. Furthermore, all configurations and operations described in the embodiments are not necessarily essential as configurations and operations in the present disclosure. Note that the same element has the same reference character, and that no redundant description of the same element will be made.

### 1. DESCRIPTION OF TERMS

### 1.1 Polarizer

The term “polarizer” is an optical element that separates light polarized in a specific direction (direction of transmission axis) from light polarized in a direction perpendicular to the specific direction.

### 1.2 Polarized Light

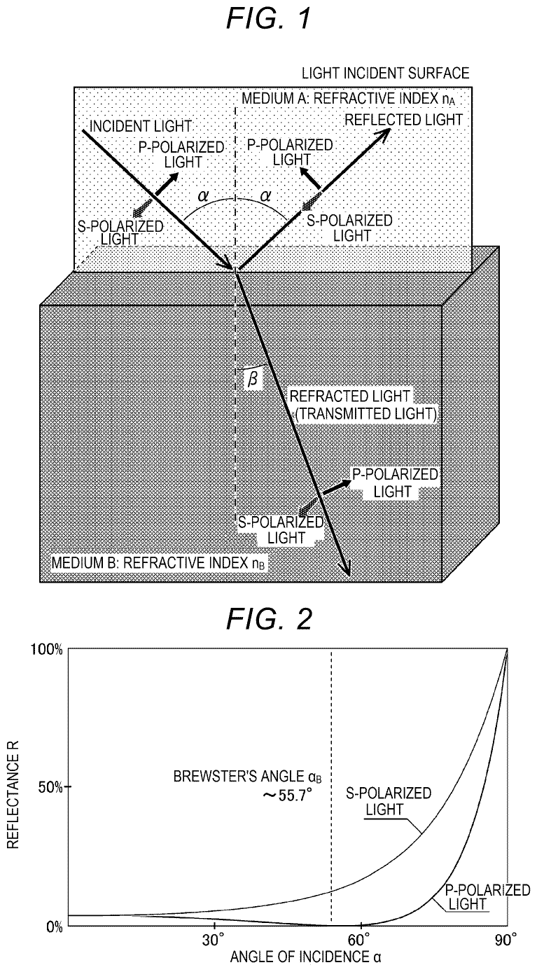

The term “polarized light” refers to light having an electric field and a magnetic field vibrating in regular directions. FIG. 1 is an explanatory diagram for polarized light, and shows an exemplary case where light from a medium A having a refractive index n_{A} enters a medium B having a refractive index n_{B}.

When light enters a medium having a different refractive index, an electric field component in a direction perpendicular to the light incident surface is called S-polarized light, and an electric field component parallel to the light incident surface is called P-polarized light, as shown in FIG. 1. According to Fresnel's law, the reflectance and transmittance for each of the polarization components change as the angle of incidence changes, as shown in FIG. 2.

FIG. 2 shows graphs illustrating the reflectance for the S-polarized light and the P-polarized light with respect to an angle of incidence a. FIG. 2 shows the graphs in a case where light incident from the air (refractive index n_{A}=1) on CaF₂ (refractive index n_{B}=1.468 with respect to wavelength 248 nm).

### 1.3 Brewster's Angle

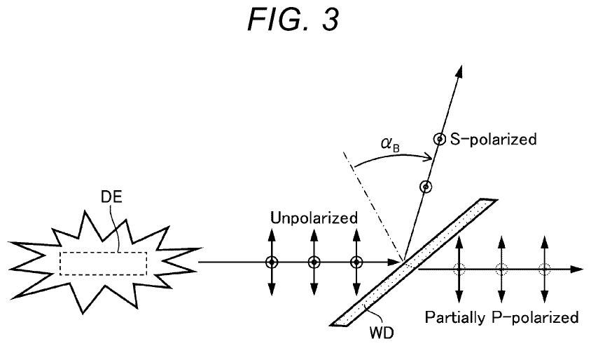

In the case of the P-polarized light, there is an angle of incidence at which the reflectance is 0% and the transmittance is 100%, and the angle is called Brewster's angle, as shown in FIG. 2. FIG. 3 shows an example of a window WD disposed in a chamber of an excimer laser. Discharge electrodes DE in the chamber face each other in the direction perpendicular to the plane of view, and discharge occurs between the electrodes. When the window WD is disposed at Brewster's angle α_{B} in a laser resonator as shown in FIG. 3, the laser beam passing through the window WD many times during the resonance operation and output via the window WD is almost entirely P-polarized with respect to the window WD.

### 1.4 Normalized Transmittance

The “normalized transmittance” is a value so normalized that the transmittance is 1.0 when the angular difference between the transmission axis of the polarizer and the polarization direction of the pulse laser light is 0, or a value so normalized that the transmittance of the window disposed at the Brewster's angle for the P-polarized light is 1.0.

### 2. OVERVIEW OF LASER APPARATUS ACCORDING TO COMPARATIVE EXAMPLE

### 2.1 Configuration

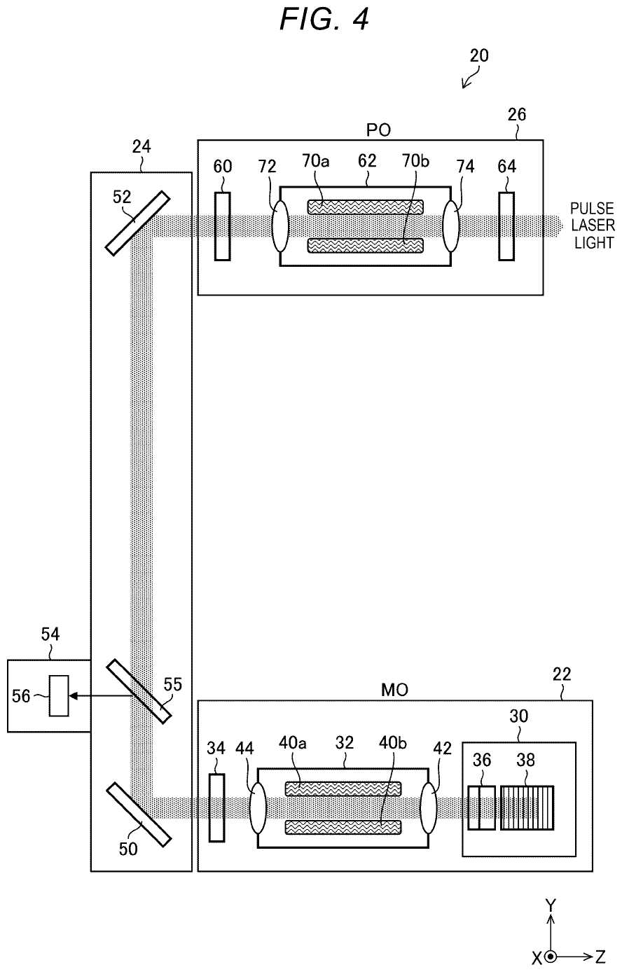

FIG. 4 is a side view schematically showing the configuration of a laser apparatus 20 according to Comparative Example. Comparative Example of the present disclosure is an aspect that the applicant is aware of as known only by the applicant, and is not a publicly known example that the applicant is self-aware of.

The laser apparatus 20 is an excimer laser apparatus including a master oscillator (MO) 22, which is an oscillation-stage laser, an MO beam steering unit 24, and a power oscillator (PO) 26, which is an amplification-stage laser. The MO 22 includes a line narrowing module (LNM) 30, a chamber 32, and an output coupling mirror 34.

The LNM 30 includes a prism beam expander 36 and a grating 38, which narrow the spectral linewidth. The prism beam expander 36 and the grating 38 are disposed in the Littrow arrangement, which causes the angle of incidence of the light incident on the grating 38 to be equal to the angle of diffraction of the light diffracted by the grating 38. The output coupling mirror 34 is a partially reflective mirror having a reflectance ranging from 40% to 60%. The output coupling mirror 34 is so disposed that the output coupling mirror 34 and the LNM 30 constitute an optical resonator.

The chamber 32 is disposed in the optical path of the optical resonator. The chamber 32 includes a pair of discharge electrodes 40a and 40b, and two windows 42 and 44, which transmit the laser light. The chamber 32 is filled with a laser gas. The laser gas contains a rare gas, a halogen gas, and a buffer gas. The rare gas may, for example, be an argon (Ar) or krypton (Kr) gas. The halogen gas may, for example, be a fluorine (F₂) gas. The buffer gas may, for example, be a neon (Ne) gas. A voltage is applied by a power supply that is not shown to the space between the discharge electrodes 40a and 40b. The power supply may be a pulse power module (PPM) including a switch and a charging capacitor.

The MO beam steering unit 24 includes highly reflective mirrors 50 and 52 and is so disposed that the laser light output from the MO 22 enters the PO 26.

An MO pulse energy monitor 54 is disposed between the highly reflective mirror 50 and the highly reflective mirror 52. The MO pulse energy monitor 54 includes a beam splitter (BS) 55 and a photosensor 56. The BS 55 is disposed in the optical path of the pulse laser light output from the MO 22 in a way that the light reflected off the BS 55 is incident on the photosensor 56.

The PO 26 includes a rear mirror 60, a chamber 62, and an output coupling mirror 64. The rear mirror 60 and the output coupling mirror 64 constitute an optical resonator, and the chamber 62 is disposed in the optical path of the optical resonator.

The configuration of the chamber 62 may be the same as that of the chamber 32. The chamber 62 includes a pair of discharge electrodes 70a and 70b, and two windows 72 and 74. The chamber 62 is filled with a laser gas. The rear mirror 60 may, for example, be a partially reflective mirror having a reflectance ranging from 50% to 90%. The output coupling mirror 64 may be a partially reflective mirror having a reflectance ranging from 10% to 30%.

### 2.2 Operation

The power supply that is not shown applies high-voltage pulses to the space between the discharge electrodes 40a and 40b in the chamber 32. When discharge occurs between the discharge electrodes 40a and 40b in the chamber 32, the laser gas is excited, and pulse laser light having ultraviolet wavelengths ranging from 150 nm to 380 nm, which form a narrowed bandwidth achieved by the optical resonator configured with the output coupling mirror 34 and the LNM 30, is output via the output coupling mirror 34.

The energy of the pulse laser light output via the output coupling mirror 34 is measured by the MO pulse energy monitor 54. The MO beam steering unit 24 causes the pulse laser light to be incident as pulse seed light on the rear mirror 60 of the PO 26.

At the timing when the pulse seed light having passed through the rear mirror 60 enters the chamber 62, a power supply that is not shown applies high-voltage pulses to the space between the discharge electrodes 70a and 70b in the chamber 62. When discharge occurs between the discharge electrodes 70a and 70b in the chamber 62, the laser gas is excited, and the pulse seed light is amplified by the Fabry-Perot-type optical resonator configured with the output coupling mirror 64 and the rear mirror 60, and the amplified pulse laser light is output via the output coupling mirror 64. Note in FIG. 4 that a direction perpendicular to the plane of view is referred to as an X direction. The traveling direction of the pulse laser light output via the output coupling mirror 64 is defined as a Z direction, and the direction perpendicular to the Z direction and the X direction is defined as a Y direction.

### 3. PROBLEMS

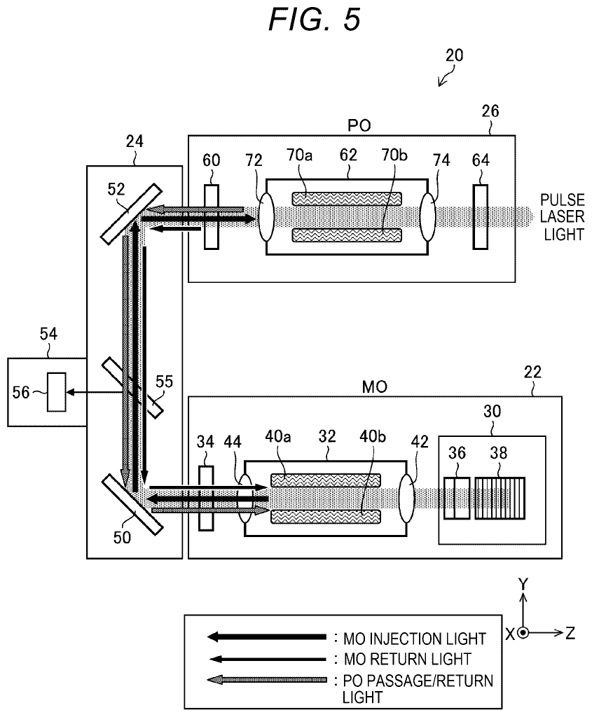

FIG. 5 shows problems with the laser apparatus 20 according to Comparative Example. When the return light from the PO 26 returns to the MO 22, the lasing performance deteriorates. The term “return light” used herein refers to the sum of two types of return light: MO return light; and PO passage/return light. The light output by the MO 22 enters the PO 26, and part of the light incident on the rear mirror 60 in the PO 26 does not travel toward the interior of the PO 26 but returns directly toward the MO 22 because the rear mirror 60 is a partially reflective mirror (having reflectance ranging from 50% to 90%). The light that does not travel into the chamber 62 of the PO 26 but is reflected off the rear mirror 60 and returns toward the MO 22 is called “MO return light”.

The light having entered the PO 26 from the MO 22 and passed through the rear mirror 60 is caused to resonate and amplified in the PO 26 and is output therefrom. As described above, since the rear mirror 60 in the PO 26 is a partially reflective mirror, part of the light having entered the chamber 62 of the PO 26 and having been amplified therein undesirably returns to the MO 22. Out of the light amplified in the PO 26, light passing through the rear mirror 60 and returning to the MO 22 is called “PO passage/return light”.

The return light becomes a heat load on the LNM 30 and other elements and may cause deterioration of the linewidth stability, pulse energy stability, and other factors. To suppress the return light that enters the MO 22, it is conceivable to dispose an optical isolator between the MO 22 and the PO 26.

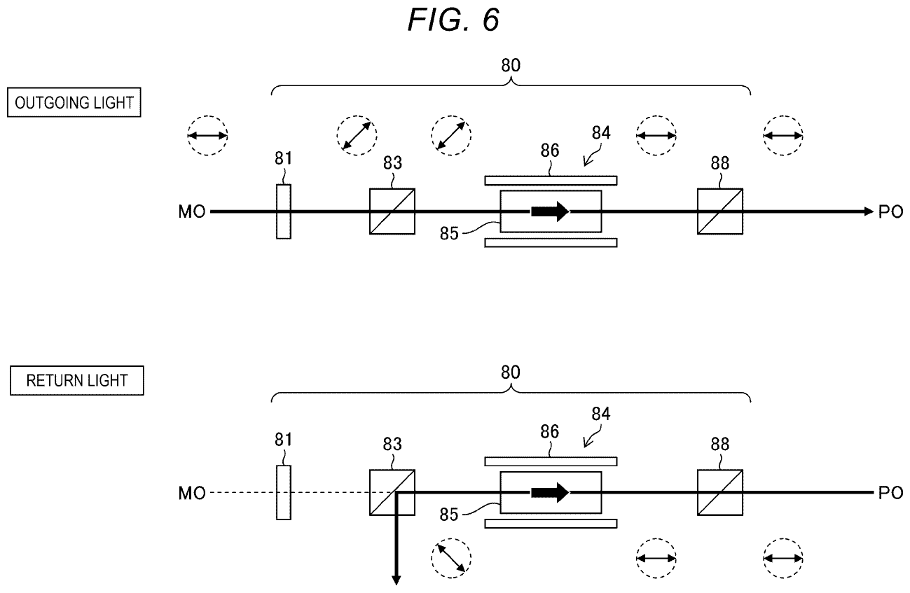

FIG. 6 shows an example of the configuration of an optical isolator 80 according to Comparative Example, which suppresses the return light. The upper portion of FIG. 6 shows how the optical isolator 80 affects the pulse laser light traveling from the MO 22 toward the PO 26 (MO injection light: outgoing light). The lower portion of FIG. 6 shows how the optical isolator 80 affects the laser light traveling from the PO 26 toward the MO 22 (return light).

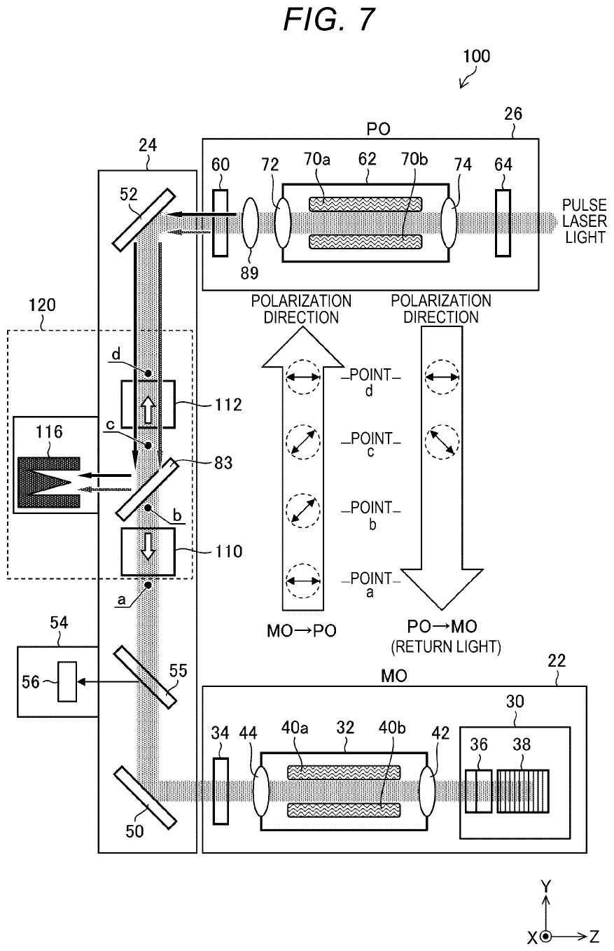

The optical isolator 80 includes a half-wave plate 81, a first polarizer 83, a Faraday rotator 84, and a second polarizer 88 arranged in this order from the MO 22 side. The Faraday rotator 84 includes a Faraday material 85 and a magnet 86. Note in FIG. 6 that the rightward arrow shown in the Faraday rotator 84 represents the direction of the magnetic field produced by the magnet 86. The double-headed arrow shown in each broken-line circle in FIG. 6 represents the direction of the polarization plane, that is, the polarization direction of the pulse laser light viewed in the traveling direction of the pulse laser light. The same applies to FIG. 7 and other figures.

In the optical isolator 80, the pulse laser light linearly polarized in a specific direction and output from the MO 22 passes through the first polarizer 83, and the polarization direction of the pulse laser light is rotated by 45 degrees clockwise by the Faraday rotator 84 to which a magnetic field is applied. After passing through the second polarizer 88, the pulse laser light enters the PO 26.

The half-wave plate 81 adjusts the polarization direction of the pulse laser light output from the MO 22 in a way that the polarization direction of the pulse laser light from the MO 22 is the same as the polarization direction of the pulse laser light that enters the PO 26. The configuration described above eliminates the need to change other modules depending on the polarization direction of the pulse laser light.

The return light from the PO 26 passes through the second polarizer 88 with the polarization direction of the return light from the PO 26 being the same as that of the light entering the PO 26, and the Faraday rotator 84, to which the magnetic field is applied, rotates the polarization direction clockwise by 45 degrees, as shown in the lower portion of FIG. 6. The polarization direction of the return light having passed through the Faraday rotator 84 is perpendicular to the transmission axis of the first polarizer 83, so that the return light is reflected off the first polarizer 83 and therefore does not enter the MO 22.

The half-wave plate 81, which adjusts the polarization direction, has low durability when used, for example, with short-wavelength excimer lasers, and therefore has a difficulty being used in a stable manner over a long period of time. An object of the present disclosure is to provide an optical isolator that can be used in a stable manner for a long period of time even with short-wavelength pulse laser light such as the light from an excimer laser.

### 4. FIRST EMBODIMENT

### 4.1 Configuration

FIG. 7 schematically shows an example of the configuration of a laser apparatus 100 according to a first embodiment. Differences in configuration between FIGS. 7 and 4 will be described. The configuration of the laser apparatus 100 differs from the configuration shown in FIG. 4 in that an optical isolator 120 is disposed between the MO 22 and the PO 26, and that a second polarizer 89 is disposed in the optical path of the optical resonator of the PO 26. The optical isolator 120 includes a first Faraday rotator 110, the first polarizer 83, a second Faraday rotator 112, and a damper 116 for return light termination. Two polarizers (83 and 88) are disposed in the optical isolator 80 according to Comparative Example shown in FIG. 6, whereas only one first polarizer 83 is disposed in the optical isolator 120 in the first embodiment.

The first Faraday rotator 110 and the second Faraday rotator 112 include respective magnets that apply magnetic fields in the opposite directions to rotate the polarization direction in the opposite directions. The direction of the magnetic field applied to the first Faraday rotator 110 shown in FIG. 7 (direction indicated by downward arrow in FIG. 7) is an example of the “first direction” in the present disclosure. The direction of the magnetic field applied to the second Faraday rotator 112 shown in FIG. 7 (direction indicated by upward arrow in FIG. 7) is an example of the “second direction” in the present disclosure.

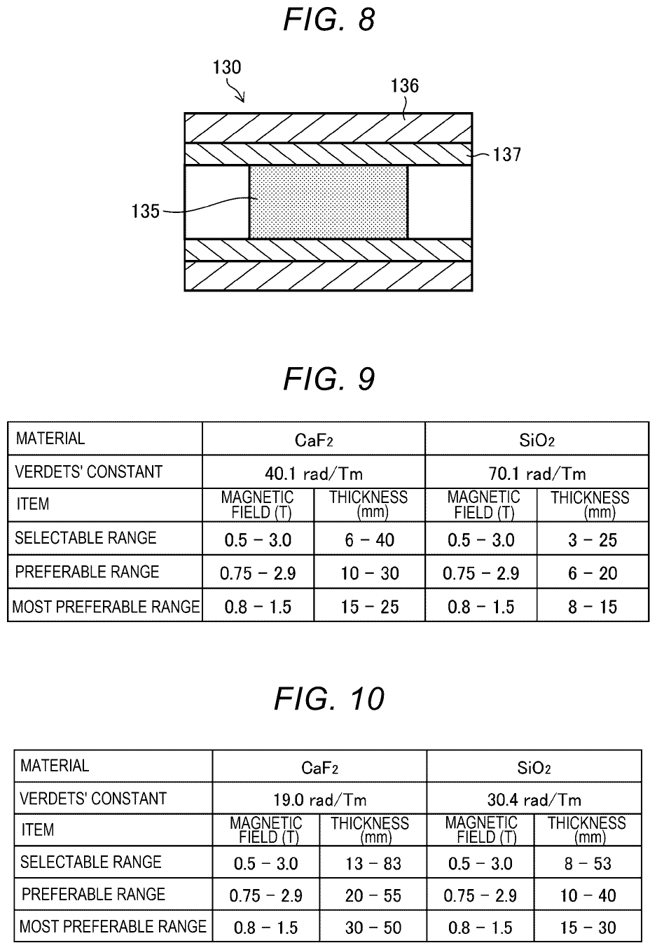

The Faraday material, size, and magnetic field of each of the first Faraday rotator 110 and the second Faraday rotator 112 are so selected that the Faraday rotator rotates the polarization direction by the angle of 45 degrees. Preferable selection conditions will be described later in detail (FIGS. 8 to 10).

The damper 116 is so disposed that the return light reflected off the first polarizer 83 is incident on the damper 116.

The second polarizer 89 is so disposed that the pulse laser light polarized in a specific direction and having entered the PO 26 passes through the second polarizer 89. The second polarizer 89 may be a polarizing beam splitter plate with a planar glass plate having a surface on which a multilayer film is formed, a polarizing beam splitter glass cube having right-angle glass cubes sandwiching multilayer films, a birefringent crystal polarizer or a plane parallel substrate disposed at Brewster's angle. The other configurations of the laser apparatus 100 may be the same as those in FIG. 4.

FIG. 7 further shows the polarization direction of the pulse laser light at locations labeled with points a, b, c, and d in the optical path between the MO 22 and the PO 26. FIG. 7 shows the polarization direction, at the locations labeled with the points a to d, of the pulse laser light propagating from the MO 22 toward the PO 26, and the polarization direction, at the locations labeled with points d and c, of the return light traveling from the PO 26 toward the MO 22.

### 4.2 Operation

The pulse laser light propagating from the MO 22 toward the PO 26 will first be described. In the laser apparatus 100, the optical isolator 120 is so disposed that the polarization direction of the pulse laser light output from the MO 22 is the same as the polarization direction of the pulse laser light entering the PO 26. The situation described above in which the two polarization directions are the same means that the angular difference between the two polarization directions falls within 10 degrees.

The polarization direction of the linearly polarized pulse laser light output from the MO 22 and polarized in a specific direction (point a) is rotated by 45 degrees counterclockwise by the first Faraday rotator 110 (point b). The counterclockwise direction is an example of the “first rotation direction” in the present disclosure, and 45 degrees is an example of the “first angle” in the present disclosure.

The first polarizer 83 is so disposed that the transmission axis thereof is parallel to the polarization direction of the pulse laser light output from the first Faraday rotator 110. The pulse laser light having a polarization direction rotated by the first Faraday rotator 110 passes through the first polarizer 83 (point c).

The pulse laser light having passed through the first polarizer 83 enters the second Faraday rotator 112, which rotates the polarization direction of the pulse laser light clockwise by 45 degrees (point d). The clockwise direction is an example of the “second rotation direction” in the present disclosure, and 45 degrees is an example of the “second angle” in the present disclosure. The pulse laser light having a polarization direction rotated by the second Faraday rotator 112 is injected into the PO 26. The polarization directions of the pulse laser light at points a and d are the same.

The pulse laser light (pulse seed light) injected into the PO 26 passes through the second polarizer 89, and the pulse laser light amplified by the optical resonator configured with the output coupling mirror 64 and the rear mirror 60 is output via the output coupling mirror 64.

The pulse laser light returning from the PO 26 toward the MO 22 will next be described. At the point d in FIG. 7, the polarization direction of the pulse laser light propagating from the MO 22 toward the PO 26 is the same as the polarization direction of the pulse laser light returning from the PO 26 toward the MO 22 (return light) because the second polarizer 89 is present in the optical path of the optical resonator of the PO 26.

The polarization direction of the return light from the PO 26 is then rotated by the second Faraday rotator 112 clockwise by 45 degrees (point c). At the point c, the polarization direction of the pulse laser light propagating from the MO 22 toward the PO 26 is perpendicular to the polarization direction of the pulse laser light returning from the PO 26 toward the MO 22. The pulse laser light returning from the PO 26 toward the MO 22 therefore does not pass through but is reflected off the first polarizer 83 and is incident on the damper 116. The damper 116 absorbs and blocks the light reflected off the first polarizer 83.

### 4.3 Specific Example of Faraday Rotators

FIG. 8 is a cross-sectional view schematically showing an example of the configuration of a Faraday rotator 130. The Faraday rotator 130 can be used as each of the first Faraday rotator 110 and the second Faraday rotator 112. The Faraday rotator 130 includes a Faraday material 135 and a magnet 136. The Faraday material 135 is a material that is transparent to light having the ultraviolet wavelengths and has a large Verdet constant. The term “transparent” means being light transmissive.

Verdet constant depends on the type of the material and the wavelength. For example, calcium fluoride (CaF₂), synthetic quartz (SiO₂), and magnesium fluoride (MgF₂) are suitable as the Faraday material 135. The Faraday material 135 is held by a holder 137.

The magnet 136 has a hollow structure, which houses the Faraday material 135 via the holder 137. The direction of the magnetic field passing through the Faraday material 135 is parallel to the light propagation direction. The direction in which the Faraday rotator 130 rotates the polarization plane (polarization direction) depends on the sign of Verdet constant and the direction of the applied magnetic field.

FIG. 9 shows preferable ranges of the magnetic field and the thickness of the Faraday material 135 in a case where the wavelength of the pulse laser light is the wavelength at which an ArF excimer laser performs oscillation. The wavelength at which an ArF excimer laser performs oscillation includes a wavelength of approximately 193 nm. FIG. 9 shows cases where the Faraday material 135 is CaF₂ and SiO₂. Note that the thickness of the Faraday material 135 is evaluated by the thickness in the optical axis direction.

FIG. 10 shows preferable ranges of the magnetic field and the thickness of the Faraday material 135 in a case where the wavelength of the pulse laser light is the wavelength at which a KrF excimer laser performs oscillation. The wavelength at which a KrF excimer laser performs oscillation includes a wavelength of approximately 248 nm. FIG. 10 shows the cases where the Faraday material 135 is CaF₂ and SiO₂.

The preferable ranges shown in FIGS. 9 and 10 have been selected based on how readily the magnetic field is achieved. The magnetic field in the most preferable range has the magnetic flux density provided by using a neodymium magnet or any other magnet that produces a large magnetic force. The thickness of the Faraday material 135 is calculated based on the selected material, the selected magnetic flux density of the magnetic field, and Verdet constant in a way that the polarization plane is rotated by 45 degrees.

As shown in FIG. 9, when the Faraday material 135 is calcium fluoride and the wavelength of the pulse laser light is the wavelength at which an ArF excimer laser performs oscillation, the magnitude of the magnetic field applied to the Faraday rotator 130 and the thickness of the Faraday material 135 in the optical axis direction preferably range from 0.5 T to 3.0 T and from 6 mm to 40 mm, respectively. The magnitude and the thickness more preferably range from 0.75 T to 2.9 T and from 10 mm to 30 mm, and most preferably range from 0.8 T to 1.5 T and from 15 mm to 25 mm. Note that the notation indicating a numerical range, such as “0.5 T to 3.0 T”, indicates a range including the numerical values shown before and after “to”. For example, the notation “0.5 T to 3.0 T” means “greater than or equal to 0.5 T and less than or equal to 3.0 T”.

When the Faraday material 135 is synthetic quartz and the wavelength of the pulse laser light is the wavelength at which the ArF excimer laser performs oscillation, the magnitude of the magnetic field applied to the Faraday rotator 130 and the thickness of the Faraday material 135 in the optical axis direction preferably range from 0.5 T to 3 T and from 3 mm to 25 mm, respectively. The magnitude and the thickness more preferably range from 0.75 T to 2.9 T and from 6 mm to 20 mm, and most preferably range from 0.8 T to 1.5 T and from 8 mm to 15 mm.

As shown in FIG. 10, when the Faraday material 135 is calcium fluoride and the wavelength of the pulse laser light is the wavelength at which a KrF excimer laser performs oscillation, the magnitude of the magnetic field applied to the Faraday rotator 130 and the thickness of the Faraday material 135 in the optical axis direction preferably range from 0.5 T to 3.0 T and from 13 mm to 83 mm, respectively. The magnitude and the thickness more preferably range from 0.75 T to 2.9 T and from 20 mm to 55 mm, and most preferably range from 0.8 T to 1.5 T and from 30 mm to 50 mm.

When the Faraday material 135 is synthetic quartz and the wavelength of the pulse laser light is the wavelength at which the KrF excimer laser performs oscillation, the magnitude of the magnetic field applied to the Faraday rotator 130 and the thickness of the Faraday material 135 in the optical axis direction preferably range from 0.5 T to 3.0 T and from 8 mm to 53 mm, respectively. The magnitude and the thickness more preferably range from 0.75 T to 2.9 T and from 10 mm to 40 mm, and most preferably range from 0.8 T to 1.5 T and from 15 mm to 30 mm.

Note that the Faraday material 135 may be divided into multiple pieces, and the total thickness of the pieces may fall within any of the ranges described above. The number of pieces to which the material is divided may, for example, be two, three, or four. The first Faraday rotator 110 and the second Faraday rotator 112 may differ from each other in terms of the Faraday material, the thickness in the optical axis direction, the magnitude of the magnetic field, and other factors. Using the first Faraday rotator 110 and the second Faraday rotator 112 having the same Faraday material, the same thickness in the optical axis direction, and the same magnitude of the magnetic field provides a configuration in which the polarization plane is rotated in opposite directions by the same amount of rotation (angle), which is a preferable configuration that is readily handled.

### 4.4 Allowable Angular Difference Between Transmission Axis of Polarizer and Polarization Direction of Laser Light

It is most preferable that the transmission axes of the first polarizer 83 and the second polarizer 89 are parallel to the polarization direction of the pulse laser light that enters the polarizers, but the transmission axes and the polarization direction are not necessarily parallel to each other in an exact sense, and an angular difference therebetween is acceptable to the extent that the difference still allows intended functions of the polarizers in practical use.

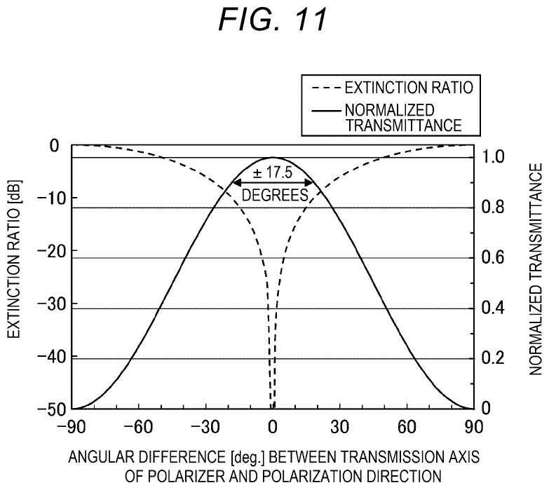

FIG. 11 shows a graph illustrating the relationship of the angular difference between the transmission axis of a polarizer and the polarization direction of the pulse laser light with an extinction ratio (dB), and a graph of the extinction ratio converted into the normalized transmittance. The left vertical axis of FIG. 11 represents the extinction ratio, and the right vertical axis of FIG. 11 represents the normalized transmittance. The normalized transmittance is a value so normalized that the transmittance at an angular difference of 0 degrees is 1.0. The first polarizer 83, through which the pulse laser light output from the first Faraday rotator 110 passes, and the second polarizer 89, through which the pulse laser light output from the second Faraday rotator 112 passes, can practically function effectively enough when the normalized transmittance of each of the rotator on which the pulse laser light is incident is greater than or equal to 0.9. FIG. 11 therefore shows that the preferable allowable range of the angular difference between the transmission axis of the first polarizer 83 or the second polarizer 89 and the polarization direction of the pulse laser light is ±17.5 degrees, within which the normalized transmittance is greater than or equal to 0.9.

According to the above discussion, the angle by which the polarization direction of the pulse laser light output from the MO 22 is rotated by the first Faraday rotator 110 and the angle by which the polarization direction of the pulse laser light having passed through the first polarizer 83 is rotated by the second Faraday rotator 112 may each fall within 45°±17.5°. Furthermore, the polarization direction of the pulse laser light traveling from the MO 22 toward the PO 26 when incident on the first polarizer 83 and the polarization direction of the pulse laser light returning from the PO 26 toward the MO 22 when incident on the first polarizer 83 after passing through the second Faraday rotator 112 may intersect with each other at an angle that falls within 90°±#17.5°. The pulse laser light that has passed through the second Faraday rotator 112 and is incident on the first polarizer 83 is thus reflected off the first polarizer 83 and absorbed by the damper 116.

### 4.5 Effects and Advantages

The laser apparatus 100 according to the first embodiment provides the advantages below.
[1] The optical isolator 120 of the laser apparatus 100 does not use the half-wave plate 81 having low durability when used at short wavelengths, and can therefore be used in a stable manner for a long period of time even with short-wavelength pulse laser light such as the light from an excimer laser.
[2] According to the laser apparatus 100, the pulse laser light returning from the PO 26 toward the MO 22 is reflected off the first polarizer 83 and absorbed by the damper 116, so that the entry of the return light into the MO 22 is suppressed. A heat load on the MO 22 is thus reduced, and the energy stability, the linewidth stability, and other factors are improved as compared with those in the configuration of Comparative Example.
[3] According to the laser apparatus 100, the light transmission efficiency from the MO 22 to the PO 26 increases as compared with the case where the second polarizer 88 is disposed between the MO 22 and the PO 26 (FIG. 6) because the second polarizer 89 is located inside the PO 26, so that the pulse seed light can be efficiently injected into the PO 26.
[4] According to the laser apparatus 100, the polarization direction of the pulse laser light is allowed to remain the same before and after the pulse laser light passes through the optical isolator 120 without use of the half-wave plate 81, which has low durability when used at short wavelengths. The amount of return light can thus be suppressed without any change of the other modules that depend on the polarization direction.
[5] According to the laser apparatus 100, the second polarizer 89 is disposed in the optical resonator of the amplification-stage laser, so that the light passes through the second polarizer 89 whenever the light travels back and forth in the optical resonator, the polarization purity can be increased as compared with the case where the polarizer is disposed outside the optical resonator.

### 5. SECOND EMBODIMENT

### 5.1 Configuration

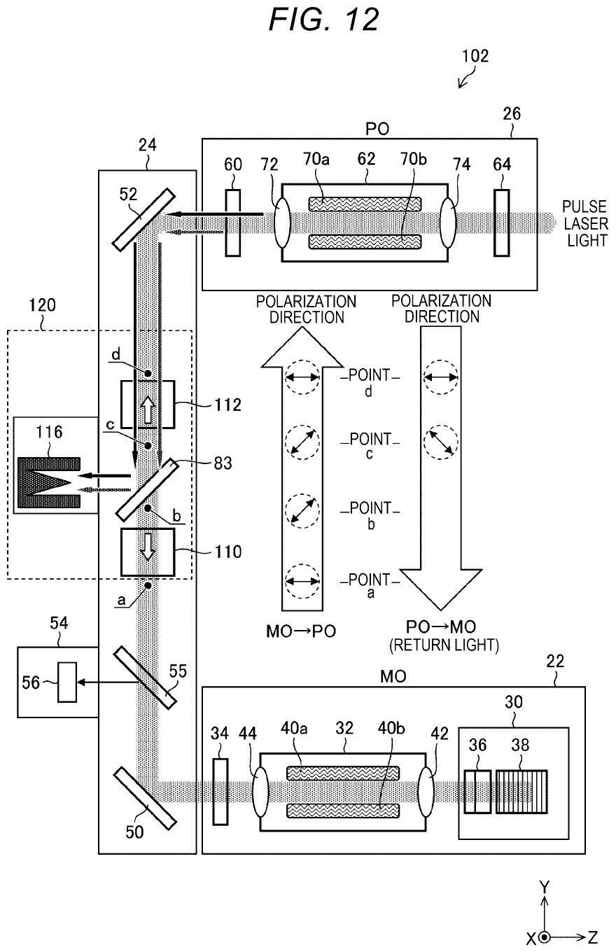

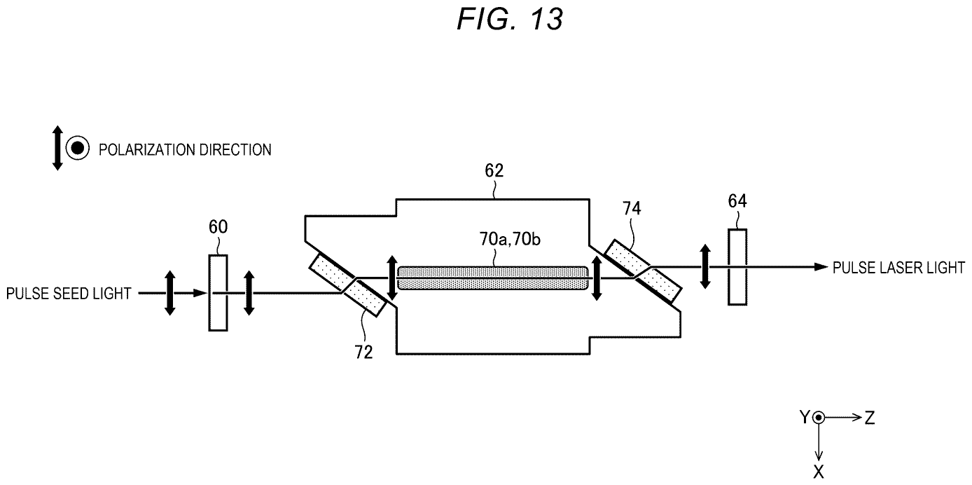

FIG. 12 schematically shows the configuration of a laser apparatus 102 according to a second embodiment. FIG. 13 schematically shows the configuration of the PO 26 in the laser apparatus 102. Differences in configuration between FIGS. 12 and 13 and FIG. 7 will be described. The configuration of the laser apparatus 102 shown in FIG. 12 differs from the configuration shown in FIG. 7 in that the second polarizer 89 is not provided, and that the windows 72 and 74 are so disposed that the angle of incidence of the light incident on the windows 72 and 74 is Brewster's angle as shown in FIG. 13. The other configurations of the laser apparatus 102 may be the same as those in FIG. 7.

The windows 72 and 74 are each so disposed that the polarized pulse laser light is incident thereon as P-polarized light. As a result, the pulse laser light passes through the windows 72 and 74 at high transmittance. The windows 72 and 74 can therefore also function as the second polarizer 89. The windows 72 and 74 may each, for example, be a calcium fluoride substrate.

### 5.2 Operation

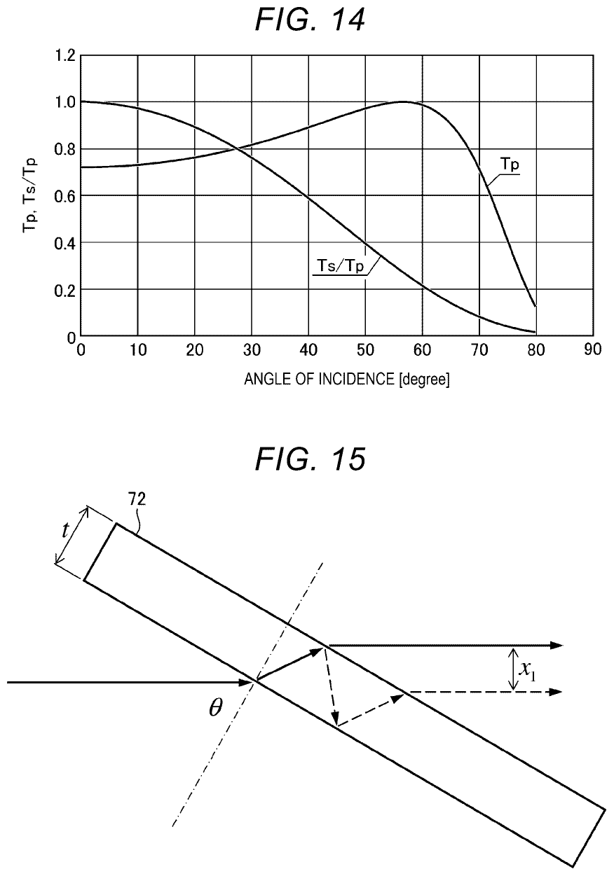

FIG. 14 shows graphs illustrating the relationship between transmittance Tp for the P-polarized light and the angle of incidence of the light incident on the windows 72 and 74, and the relationship between a ratio (Ts/Tp) of transmittance Ts for the S-polarized light to the transmittance Tp for the P-polarized light and the angle of incidence of the light incident on the windows 72 and 74. Note that the transmittance in FIG. 14 is a value obtained when the light passes through the windows 72 and 74 twice, that is, when the light travels back and forth once in the optical resonator.

The P-polarized light passes through the windows 72 and 74 at high transmittance even when the angle of incidence is not Brewster's angle, as shown in FIG. 14. The transmittance Tp for the P-polarized light is higher than or equal to 0.9 when the angle of incidence is greater than or equal to 45 degrees and less than or equal to 65 degrees. When the angle of incidence decreases, however, the ratio Ts/Tp increases, so that proportion of the S-polarized light passing through the windows 72 and 74 increases. The angle of incidence is therefore preferably greater than 45 degrees, at which the ratio Ts/Tp is less than 0.5. Therefore, when the angle of incidence with respect to the windows 72 and 74 is greater than 45 degrees and less than or equal to 65 degrees, the windows 72 and 74 can also function as the second polarizer 89.

FIG. 15 is an explanatory diagram showing the optical path of the S-polarization component of the pulse laser light propagating in the window 72 disposed at Brewster's angle. In FIG. 15, the solid-line arrows indicate the optical path of the light passing through the substrate of the window 72, and the broken-line arrows indicate the optical path of the light reflected off the surfaces of the substrate multiple times.

To increase the polarization separation factor of the window 72 disposed at Brewster's angle, it is desirable that the optical path of the light passing through the window 72 (solid-line arrows) and the optical path of the light reflected off the window 72 multiple times (broken-line arrows) are spatially separate from each other.

When the two optical paths are spatially separate from each other, the light reflected multiple times does not pass through the discharge region in the chamber 62 and is therefore not amplified. The polarization separation ratio thus increases. Note that the P-polarization and S-polarization components of the pulse laser light having passed through the window 72 pass through the discharge region in the chamber 62, are amplified, and are output as the pulse laser light.

The spatial distance between the optical path of the light having passed through the window 72 and the optical path of the light reflected off the window 72 multiple times (inter-optical-path distance) varies in accordance with the thickness of the window 72. Increasing the thickness of the window 72 can spatially separate the two optical paths from each other.

A first inter-optical-path distance x₁ between the light having passed through the window 72 and the light reflected off the window 72 multiple times can be expressed by formula (1) below, where t is the thickness of the window 72, 0 is the angle of incidence, and n is the refractive index.

$${x}_{1} = t \frac{sin ( 2 θ )}{\sqrt{{n}^{2} - {sin}^{2} θ}} \qquad ( 1 )$$

The light reflected off the window 72 multiple times is not amplified when x₁>D, where D is the width of the pulse laser light (width at 1/e²) in the direction perpendicular to the discharge direction.

The thickness t of the window 72 is, for example, greater than or equal to 5 mm.

The window 74 is configured in the same manner as the window 72. Note that the windows 72 and 74 may have the same thickness or different thicknesses.

### 5.3 Effects and Advantages

The laser apparatus 102 according to the second embodiment can provide advantages that are the same as those provided by the laser apparatus 100 according to the first embodiment. Furthermore, according to the laser apparatus 102, since the number of optical elements in the PO 26 can be reduced as compared with that in the laser apparatus 100, it can be expected that the life of each of the optical elements can be prolonged and the transmittance thereof can be increased.

Moreover, according to the laser apparatus 102, in which the windows 72 and 74 are disposed at Brewster's angle in the optical resonator of the PO 26, so that the light passes through the windows 72 and 74 whenever the light travels back and forth in the optical resonator, the polarization purity can be increased as compared with the case where the polarizer and the windows are disposed outside the optical resonator.

### 6. THIRD EMBODIMENT

### 6.1 Configuration

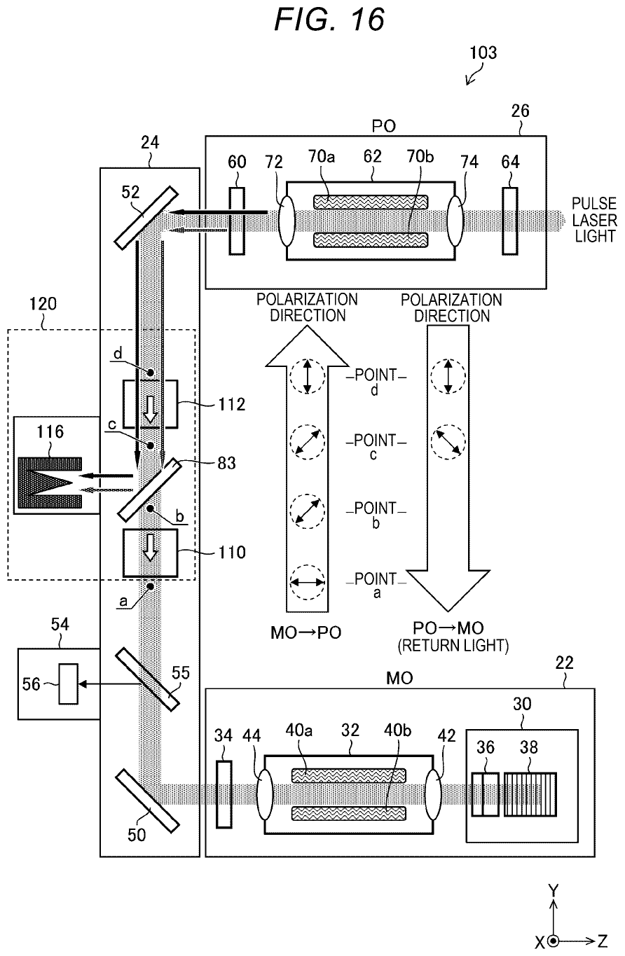

FIG. 16 schematically shows the configuration of a laser apparatus 103 according to a third embodiment. Differences in configuration between FIG. 16 and FIGS. 12 and 13 (second embodiment) will be described. The laser apparatus 103 shown in FIG. 16 differs from the laser apparatus 102 in that the optical isolator 120 is so disposed that the polarization direction of the pulse laser light output from the MO 22 is perpendicular to the polarization direction of the pulse laser light entering the PO 26. The situation described above in which the polarization directions are perpendicular to each other means that the angular difference between the two polarization directions is greater than or equal to 85 degrees and less than or equal to 95 degrees.

The optical isolator 120 shown in FIG. 16, for example, sets the following two directions in the same direction: the direction of the magnetic field applied to the second Faraday rotator 112; and the direction of the magnetic field applied to the first Faraday rotator 110. The polarization direction of the pulse seed light entering the PO 26 is thus perpendicular to the polarization direction of the pulse seed light entering the PO 26 of the laser apparatus 102.

The light incident surfaces of the windows 72 and 74 of the laser apparatus 103 are therefore perpendicular to the light incident surfaces of the windows 72 and 74 of the laser apparatus 102 according to the second embodiment.

The angle of incidence of the pulse laser light incident on the windows 72 and 74 of the laser apparatus 103 is preferably Brewster's angle, as in the laser apparatus 102. Note that the angle of incidence of the pulse laser light incident on the windows 72 and 74 is not limited to Brewster's angle, and when the angle of incidence is greater than 45 degrees and less than or equal to 65 degrees, the windows 72 and 74 can also function as the second polarizer 89, as in the second embodiment. The other configurations of the laser apparatus 103 may be the same as those of the laser apparatus 102.

### 6.2 Operation

Regarding the operation of the optical isolator 120 (FIG. 16) of the laser apparatus 103 according to the third embodiment, differences from FIG. 12 will be described. In the optical isolator 120 shown in FIG. 16, the pulse laser light (point c) having passed through the first polarizer 83 enters the second Faraday rotator 112, which rotates the polarization direction of the pulse laser light counterclockwise by 45 degrees (point d). The polarization directions of the pulse laser light at points a and d in FIG. 16 are perpendicular to each other.

The pulse laser light having a polarization direction rotated by the second Faraday rotator 112 is injected into the PO 26, and the pulse laser light amplified by the optical resonator of the PO 26 is output via the output coupling mirror 64.

Regarding the pulse laser light returning from the PO 26 toward the MO 22, the polarization direction of the pulse laser light propagating from the MO 22 toward the PO 26 is the same as the polarization direction of the pulse laser light returning from the PO 26 toward the MO 22 (return light) at the point d in FIG. 16.

The polarization direction of the return light from the PO 26 is rotated by the second Faraday rotator 112 counterclockwise by 45 degrees (point c). That is, the direction of the rotation of the polarization direction rotated by the second Faraday rotator 112 is the same as the rotation direction of the polarization direction rotated by the first Faraday rotator 110. The other operations of the laser apparatus 103 are the same as those of the laser apparatus 102.

### 6.3 Effects and Advantages

The laser apparatus 103 according to the third embodiment can provide advantages that are the same as those provided by the laser apparatus 102 according to the second embodiment.

### 7. FOURTH EMBODIMENT

### 7.1 Configuration

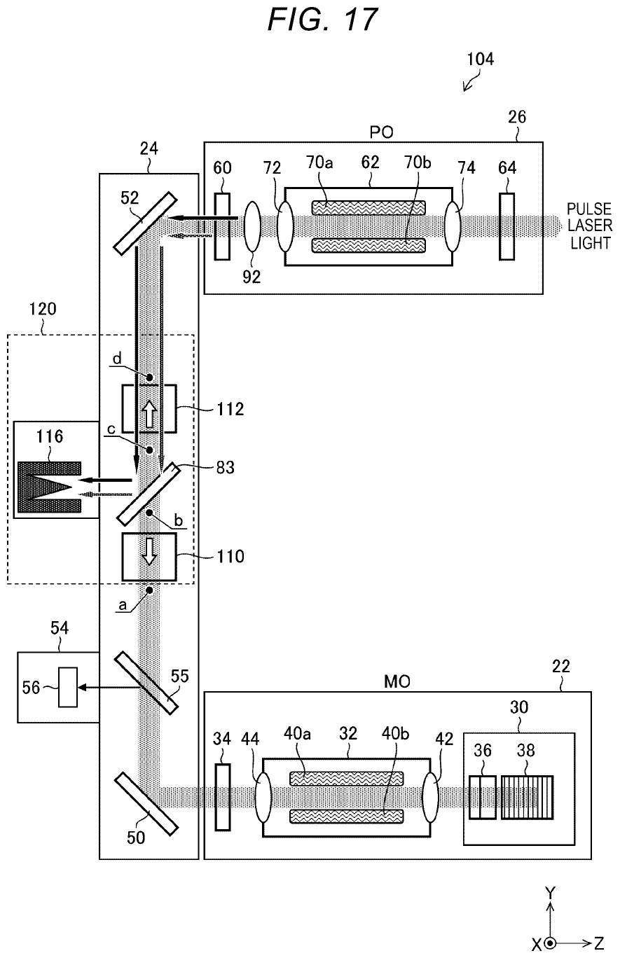

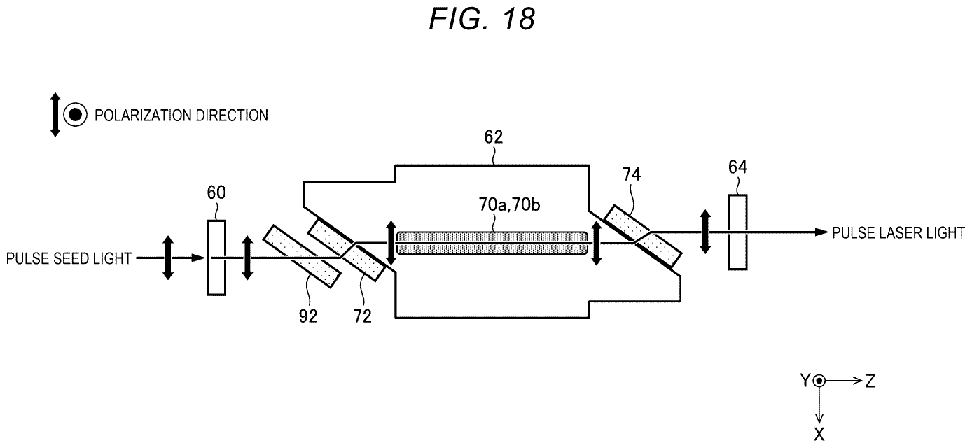

FIG. 17 schematically shows the configuration of a laser apparatus 104 according to a fourth embodiment. FIG. 18 schematically shows the configuration of the PO 26 in the laser apparatus 104. Differences in configuration between FIGS. 17 and 18 and FIGS. 12 and 13 (second embodiment) will be described. The configuration of the laser apparatus 104 differs from the configuration shown in FIG. 12 in that a plane parallel substrate 92 is provided between the rear mirror 60 of the PO 26 and the window 72 and in parallel to the window 72. The angle of incidence with respect to the plane parallel substrate 92 and the window 72 is not limited to Brewster's angle, and may be greater than 45 degrees and less than or equal to 70 degrees.

The plane parallel substrate 92 may, for example, be a calcium fluoride substrate, as the windows 72 and 74. The other configurations of the laser apparatus 104 may be the same as those in the second embodiment.

### 7.2 Operation

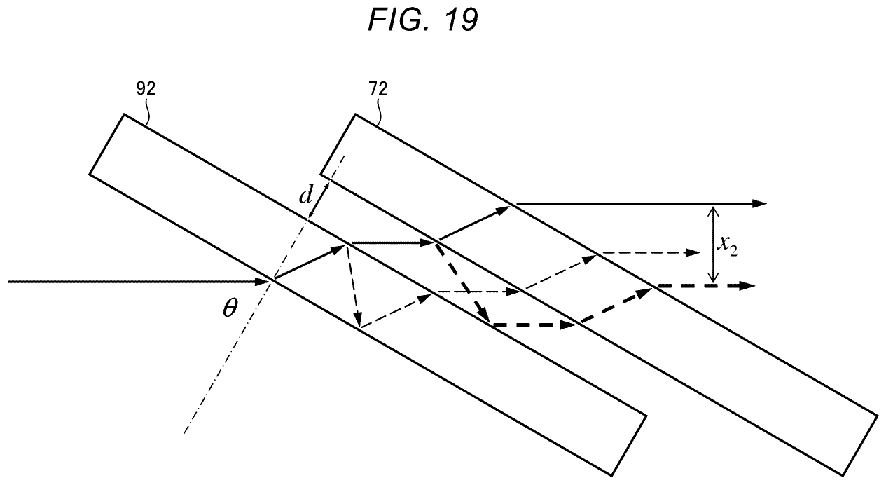

FIG. 19 is an explanatory diagram showing the optical path of the S-polarization component of the pulse laser light propagating through the plane parallel substrate 92 and the window 72 that are disposed at Brewster's angle. In FIG. 19, the solid-line arrows indicate the optical path of the light passing through the window 72 and the plane parallel substrate 92, the broken-line arrows indicate the optical path of the light reflected off the surfaces of the plane parallel substrate 92 multiple times, and the thick broken-line arrows indicate the optical path of the light reflected off the window 72 and the plane parallel substrate 92 multiple times.

To increase the polarization separation factor of the window 72 disposed at Brewster's angle, it is desirable that the optical path of the light passing through the window 72 and the plane parallel substrate 92 (solid-line arrows) and the optical path of the light reflected off the window 72 and the plane parallel substrate 92 multiple times (thick broken-line arrows) are spatially separate from each other.

When the two optical paths are spatially separate from each other, the light reflected multiple times does not pass through the discharge region in the chamber 62 and is therefore not amplified. The polarization separation ratio thus increases. Note that the P-polarization and S-polarization components of the pulse laser light having passed through the window 72 and the plane parallel substrate 92 pass through the discharge region in the chamber 62, are amplified, and are output as the pulse laser light.

The spatial distance d between the optical path of the light passing through the window 72 and the plane parallel substrate 92 and the optical path of the light reflected off the window 72 and the plane parallel substrate 92 multiple times changes in accordance with the distance d between the window 72 and the plane parallel substrate 92. Increasing the distance d can spatially separate the two optical paths from each other.

A second inter-optical-path distance x₂, which is the spatial distance between the light passing through the window 72 and the plane parallel substrate 92 and the light reflected off the window 72 and the plane parallel substrate 92 multiple times (thick broken-line arrows), can be expressed by formula (2) below, where θ represents the angle of incidence with respect to the plane parallel substrate 92.

$${x}_{2} = d \frac{sin ( 2 θ )}{cos θ} \qquad ( 2 )$$

The light reflected off the window 72 and the plane parallel substrate 92 multiple times is not amplified when x₁>D and x₂>D, where D is the width of the pulse laser light (width at 1/e²) in the direction perpendicular to the discharge direction.

The distance d between the window 72 and the plane parallel substrate 92 is, for example, greater than or equal to 3 mm. Note that the window 72 and the plane parallel substrate 92 may have the same thickness or different thicknesses.

### 7.3 Effects and Advantages

The laser apparatus 104 according to the fourth embodiment can provide advantages that are the same as those provided by the laser apparatus 102 according to the second embodiment. Furthermore, the laser apparatus 104 can provide pulse laser light having polarization purity higher than that in the second embodiment.

### 8. ELECTRONIC DEVICE MANUFACTURING METHOD

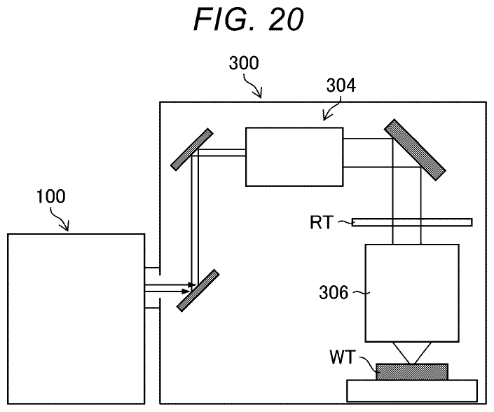

FIG. 20 schematically shows an example of the configuration of an exposure apparatus 300. The exposure apparatus 300 includes an illumination optical system 304 and a projection optical system 306. The illumination optical system 304 illuminates a reticle pattern of a reticle that is not shown but is placed on a reticle stage RT with the laser light incident from the laser apparatus 100. The projection optical system 306 performs reduction projection on the laser light having passed through the reticle to bring the laser light into focus on a workpiece that is not shown but is placed on a workpiece table WT. The workpiece is a photosensitive substrate onto which a photoresist has been applied, such as a semiconductor wafer.

The exposure apparatus 300 translates the reticle stage RT and the workpiece table WT in synchronization with each other to expose the workpiece to the laser light having reflected the reticle pattern. Semiconductor devices can be manufactured by transferring the reticle pattern onto the semiconductor wafer in the exposure step described above and then carrying out multiple other steps. The semiconductor devices are an example of the “electronic devices” in the present disclosure. The laser apparatus 100 may be replaced with the laser apparatus 102, 103 or 104 described in the second to fourth embodiments to generate the laser light.

### 9. OTHERS

The above description is intended to be illustrative, and the present disclosure is not limited thereto. It is therefore apparent to those skilled in the art that changes can be made to the embodiments of the present disclosure without departing from the scope of the appended claims. It is also apparent for those skilled in the art that the embodiments of the present disclosure are combined with each other.

The terms used throughout the present specification and the appended claims should be interpreted as non-limiting terms. For example, terms such as “include”, “have”, “comprise”, and “contain” should not be interpreted to be exclusive of elements other than those described in the present specification and the appended claims. Further, indefinite articles “a/an” described in the present specification and the appended claims should be interpreted to mean “at least one” or “one or more”. Further, the term “at least one of A, B, and C” should be interpreted to mean any of A, B, C, A+B, A+C, B+C, and A+B+C. Moreover, the term described above should be interpreted to include combinations of any thereof and any other than A, B, and C.

What is claimed is:

1. A laser apparatus comprising:
an oscillation-stage laser;
an amplification-stage laser configured to amplify, as seed light, linearly polarized pulse laser light output from the oscillation-stage laser and having an ultraviolet wavelength;
an optical isolator disposed in an optical path between the oscillation-stage laser and the amplification-stage laser, the optical isolator including
a first Faraday rotator configured to rotate a polarization direction of the pulse laser light output from the oscillation-stage laser by a first angle in a first rotation direction by a magnetic field in a first direction,
a first polarizer having normalized transmittance greater than or equal to 0.9 for the pulse laser light output from the first Faraday rotator, and
a second Faraday rotator configured to rotate the polarization direction of the pulse laser light passing through the first polarizer by a second angle in a second rotation direction opposite to the first rotation direction by a magnetic field in a second direction opposite to the first direction; and
a second polarizer disposed in an optical resonator of the amplification-stage laser and having normalized transmittance greater than or equal to 0.9 for the seed light.

2. The laser apparatus according to claim 1, wherein
the second polarizer is a polarizing beam splitter plate, a polarizing beam splitter glass cube, or a calcium fluoride substrate.

3. The laser apparatus according to claim 1, wherein
the second polarizer is a calcium fluoride substrate, and
an angle of incidence of the pulse laser light incident on the calcium fluoride substrate is greater than 45 degrees and less than or equal to 65 degrees.

4. The laser apparatus according to claim 1, wherein
the pulse laser light output from the oscillation-stage laser and the pulse laser light entering the amplification-stage laser have the same polarization direction.

5. The laser apparatus according to claim 1, wherein
the amplification-stage laser includes a chamber including a window configured to transmit the pulse laser light,
the window is configured to receive the pulse laser light incident thereon at an angle of incidence greater than 45 degrees and less than or equal to 65 degrees, and to serve as the second polarizer.

6. The laser apparatus according to claim 5, wherein
a first inter-optical-path distance x₁ calculated by a formula below is greater than a width of the pulse laser light in a direction perpendicular to a discharge direction.
$${x}_{1} = t \frac{sin ( 2 θ )}{\sqrt{{n}^{2} - {sin}^{2} θ}}$$
where t represents a thickness of the window, θ represents an angle of incidence with respect to the window, and n represents a refractive index of the window.

7. The laser apparatus according to claim 5, wherein
the amplification-stage laser further includes a plane parallel substrate disposed in parallel to the window.

8. The laser apparatus according to claim 7, wherein
a second inter-optical-path distance x₂ calculated by a formula below is greater than a width of the pulse laser light in a direction perpendicular to a discharge direction.
$${x}_{2} = d \frac{sin ( 2 θ )}{cos θ}$$
where d represents a distance between the window and the plane parallel substrate, and θ represents an angle of incidence with respect to the plane parallel substrate.

9. The laser apparatus according to claim 7, wherein
the window and the plane parallel substrate are each a calcium fluoride substrate.

10. The laser apparatus according to claim 1, wherein
an angular difference between the polarization direction of the pulse laser light output from the first Faraday rotator and a transmission axis of the first polarizer is less than or equal to 17.5 degrees, and
an angular difference between the polarization direction of the pulse laser light output from the second Faraday rotator and a transmission axis of the second polarizer is less than or equal to 17.5 degrees.

11. The laser apparatus according to claim 1, wherein
an angular difference between the first angle and the second angle is less than or equal to 17.5 degrees.

12. The laser apparatus according to claim 1, wherein
the first and second angles each fall within a range of 45±17.5 degrees,
the polarization direction of the pulse laser light traveling from the oscillation-stage laser toward the amplification-stage laser when incident on the first polarizer and the polarization direction of the pulse laser light returning from the amplification-stage laser toward the oscillation-stage laser, when incident on the first polarizer after passing through the second Faraday rotator intersect with each other at an angle within a range of 90±17.5 degrees, and
the pulse laser light that has passed through the second Faraday rotator and is incident on the first polarizer is reflected off the first polarizer.

13. The laser apparatus according to claim 12, wherein
a wavelength of the pulse laser light is a wavelength at which an ArF excimer laser performs oscillation,
a Faraday material contained in each of the first and second Faraday rotators is calcium fluoride, and
a thickness of each Faraday material in an optical axis direction is greater than or equal to 6 mm and less than or equal to 40 mm.

14. The laser apparatus according to claim 12, wherein
a wavelength of the pulse laser light is a wavelength at which an ArF excimer laser performs oscillation,
a Faraday material contained in each of the first and second Faraday rotators is synthetic quartz, and
a thickness of each Faraday material in an optical axis direction is greater than or equal to 3 mm and less than or equal to 25 mm.

15. The laser apparatus according to claim 12, wherein
a wavelength of the pulse laser light is a wavelength at which a KrF excimer laser performs oscillation,
a Faraday material contained in each of the first and second Faraday rotators is calcium fluoride, and
a thickness of each Faraday material in an optical axis direction is greater than or equal to 13 mm and less than or equal to 83 mm.

16. The laser apparatus according to claim 12, wherein
a wavelength of the pulse laser light is a wavelength at which a KrF excimer laser performs oscillation,
a Faraday material contained in each of the first and second Faraday rotators is synthetic quartz, and
a thickness of each Faraday material in an optical axis direction is greater than or equal to 8 mm and less than or equal to 53 mm.

17. A laser apparatus comprising:
an oscillation-stage laser;
an amplification-stage laser configured to amplify, as seed light, linearly polarized pulse laser light output from the oscillation-stage laser and having an ultraviolet wavelength;
an optical isolator disposed in an optical path between the oscillation-stage laser and the amplification-stage laser, the optical isolator including
a first Faraday rotator configured to rotate a polarization direction of the pulse laser light output from the oscillation-stage laser by a first angle in a first rotation direction by a magnetic field in a first direction,
a first polarizer having normalized transmittance greater than or equal to 0.9 for the pulse laser light output from the first Faraday rotator, and
a second Faraday rotator configured to rotate the polarization direction of the pulse laser light passing through the first polarizer by a second angle in a direction that is the same as the first rotation direction by a magnetic field in a direction that is the same as the first direction; and
a second polarizer disposed in an optical resonator of the amplification-stage laser and having normalized transmittance greater than or equal to 0.9 for the seed light.

18. The laser apparatus according to claim 17, wherein
the polarization direction of the pulse laser light output from the oscillation-stage laser and the polarization direction of the pulse laser light entering the amplification-stage laser are perpendicular to each other.

19. The laser apparatus according to claim 17, wherein
the amplification-stage laser includes a chamber including a window configured to transmit the pulse laser light,
the window is configured to receive the pulse laser light incident thereon at an angle of incidence greater than 45 degrees and less than or equal to 65 degrees, and to serve as the second polarizer.

20. An electronic device manufacturing method comprising:
generating laser light amplified by an amplification-stage laser of a laser apparatus;
outputting the amplified laser light to an exposure apparatus; and
exposing a photosensitive substrate to the laser light in the exposure apparatus to manufacture electronic devices,
the laser apparatus including
an oscillation-stage laser,
an amplification-stage laser configured to amplify, as seed light, linearly polarized pulse laser light output from the oscillation-stage laser and having an ultraviolet wavelength,
an optical isolator disposed in an optical path between the oscillation-stage laser and the amplification-stage laser, the optical isolator including
a first Faraday rotator configured to rotate a polarization direction of the pulse laser light output from the oscillation-stage laser by a first angle in a first rotation direction by a magnetic field in a first direction,
a first polarizer having normalized transmittance greater than or equal to 0.9 for the pulse laser light output from the first Faraday rotator, and
a second Faraday rotator configured to rotate the polarization direction of the pulse laser light passing through the first polarizer by a second angle in a second rotation direction opposite to the first rotation direction by a magnetic field in a second direction opposite to the first direction, and
a second polarizer disposed in an optical resonator of the amplification-stage laser and having normalized transmittance greater than or equal to 0.9 for the seed light.
